(19) United States
(12) Patent Application Publication
(10) Pub. No.: US 2022/0209110 A1
(43) Pub. Date: Jun. 30, 2022

(54) ELECTRONIC DEVICE AND METHOD FOR FABRICATING THE SAME

(71) Applicant: SK hynix inc., Icheon (KR)

(72) Inventors: Deok Lae AHN, Icheon (KR); Min Jin CHO, Icheon (KR); Won Ki JU, Icheon (KR)

(21) Appl. No.: 17/221,616

(22) Filed: Apr. 2, 2021

(30) Foreign Application Priority Data
Dec. 24, 2020 (KR) 10-2020-0182895

(51) Int. Cl. H01L 45/00; G11C 13/00

(52) U.S. Cl. CPC H01L 45/1253; G11C 13/0023; H01L 45/16; H01L 45/149

(57) ABSTRACT

An electronic device comprising a semiconductor memory including a plurality of memory cells is provided. Each of the plurality of memory cells includes: a first electrode layer; a variable resistance layer disposed over the first electrode layer; a second electrode layer disposed over the variable resistance layer; and an interface electrode layer interposed between the first electrode layer and the variable resistance layer or between the second electrode layer and the variable resistance layer. The interface electrode layer includes a porous metal-containing layer.

### CROSS-REFERENCE TO RELATED APPLICATION

This application claims priority under 35 U.S.C. § 119 to Korean Patent Application No. 10-2020-0182895 filed on Dec. 24, 2020, which is incorporated herein by reference in its entirety.

### BACKGROUND

### 1. Technical Field

This patent document relates to memory circuits or devices and their applications in electronic devices or systems.

### 2. Related Art

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices can store data using a characteristic of switching between different resistance states according to an applied voltage or current. For example, these semiconductor devices may include an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes various embodiments of an electronic device capable of improving operating characteristics of a semiconductor memory and substantially preventing process defects, and a method for fabricating the same.

In an embodiment, an electronic device includes a semiconductor memory including a plurality of memory cells, and each of the plurality of memory cells includes: a first electrode layer; a variable resistance layer disposed over the first electrode layer; a second electrode layer disposed over the variable resistance layer; and an interface electrode layer interposed between the first electrode layer and the variable resistance layer or between the second electrode layer and the variable resistance layer, wherein the interface electrode layer includes a porous metal-containing layer.

In another embodiment, a method for fabricating an electronic device comprising a semiconductor memory including a plurality of memory cells, includes: forming an initial multi-layered structure for forming the plurality of memory cells over a substrate, the initial multi-layered structure including an initial first electrode layer, an initial variable resistance layer disposed over the initial first electrode layer, an initial second electrode layer disposed over the initial variable resistance layer, and an initial interface electrode layer interposed between the initial first electrode layer and the initial variable resistance layer or between the initial second electrode layer and the initial variable resistance layer; and selectively etching the initial multi-layered structure to form a multi-layered structure including a first electrode layer, a variable resistance layer disposed over the first electrode layer, a second electrode layer disposed over the variable resistance layer, and an interface electrode layer interposed between the first electrode layer and the variable resistance layer or between the second electrode layer and the variable resistance layer, wherein the interface electrode layer includes a porous metal-containing layer.

### BRIEF DESCRIPTION OF THE DRAWINGS

FIGS. 1A and 1B are views illustrating a semiconductor memory according to an embodiment of the present disclosure.

FIGS. 2A, 2B, 2C, 2D, and 2E are cross-sectional views illustrating a method of forming a memory cell according to an embodiment of the present disclosure.

FIG. 3A is a perspective view illustrating a first interface electrode layer or a second interface electrode layer according to an embodiment of the present disclosure.

FIG. 3B is a cross-sectional view illustrating the first interface electrode layer or the second interface electrode layer shown in FIG. 3A, according to an embodiment of the present disclosure.

FIG. 4 is an example of configuration diagram of a microprocessor implementing memory circuitry based on the disclosed technology.

FIG. 5 is an example of configuration diagram of a processor implementing memory circuitry based on the disclosed technology.

FIG. 6 is an example of configuration diagram of a system implementing memory circuitry based on the disclosed technology.

FIG. 7 is an example of configuration diagram of a memory system implementing memory circuitry based on the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

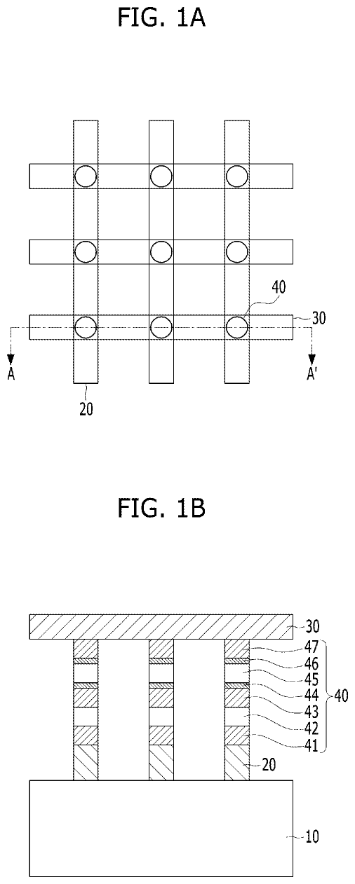

FIGS. 1A and 1B are views illustrating a semiconductor memory according to an embodiment of the present disclosure. FIG. 1A is a plan view, and FIG. 1B is a cross-sectional view taken along a line A-A′ of FIG. 1A.

Referring to FIGS. 1A and 1B, a semiconductor memory according to the present embodiment may include a substrate 10, first lines 20 formed over the substrate 10 and extending in a first direction crossing the line A-A′, second lines 30 formed over the first lines 20 to be spaced apart from the first lines 20 and extending in a second direction parallel to the A-A′ line, and memory cells 40 disposed between the first lines 20 and the second lines 30 and overlapping crossing regions of the first lines 20 and the second lines 30, respectively.

In a plan view, the memory cell 40 may have a circular shape, but the planar shape of the memory cell 40 may vary as long as it overlaps the crossing region of the first line 20 and the second line 30. For example, the memory cell 40 may have a rectangular planar shape in which a first pair of sidewalls in the first direction are substantially aligned with the first line 20 and a second pair of sidewalls in the second direction are substantially aligned with the second line 30. Spaces between the first lines 20, spaces between the memory cells 40, and spaces between the second lines 30 may be filled with an insulating material (not shown).

Here, the substrate 10 may include a required lower structure (not shown). For example, the substrate 10 may include a driving circuit (not shown) that is electrically connected to the first lines 20, or the second lines 30, or the first and second lines 20 and 30 to control them.

The first line 20 and the second line 30 may include one or more conductive materials, for example, a metal such as platinum (Pt), tungsten (W), aluminum (Al), copper (Cu), or tantalum (Ta), a metal nitride such as titanium nitride (TiN) or tantalum nitride (TaN), or a combination thereof. The first line 20 and the second line 30 may have a single-layered structure or a multi-layered structure.

The memory cell 40 may include a lower electrode layer 41, a selection element layer 42, an intermediate electrode layer 43, a variable resistance layer 45, and an upper electrode layer 47 that are sequentially stacked. Further, the memory cell 40 may include a first interface electrode layer 44 between the variable resistance layer 45 and the intermediate electrode layer 43, and a second interface electrode layer 46 between the variable resistance layer 45 and the upper electrode layer 47.

The lower electrode layer 41 and the upper electrode layer 47 may be positioned at lower and upper ends of the memory cell 40, respectively, and may function to transmit a voltage or current required for the operation of the memory cell 40. The intermediate electrode layer 43 may function to electrically connect the selection element layer 42 and the variable resistance layer 45 while physically separating them. One or more of the lower electrode layer 41, the intermediate electrode layer 43, and the upper electrode layer 47 may include one or more conductive materials, for example, a metal such as platinum (Pt), tungsten (W), aluminum (Al), copper (Cu), or tantalum (Ta), a metal nitride such as titanium nitride (TiN) or tantalum nitride (TaN), or a combination thereof. Alternatively, one or more of the lower electrode layer 41, the intermediate electrode layer 43, and the upper electrode layer 47 may include a carbon electrode.

The selection element layer 42 may function to substantially prevent current leakage that may occur between the memory cells 40 sharing the first line 20 or the second line 30. To this end, the selection element layer 42 may have a threshold switching characteristic, that is, a characteristic for substantially blocking or limiting a current when a magnitude of an applied voltage is less than a predetermined threshold value and for allowing a current to abruptly increase above the threshold value. The threshold value may be referred to as a threshold voltage, and selection element layer 42 may be in a turn-on state or a turn-off state based on the threshold voltage. The selection element layer 42 may include a diode, an OTS (Ovonic Threshold Switching) material such as a chalcogenide material, an MIEC (Mixed Ionic Electronic Conducting) material such as a metal containing chalcogenide material, an MIT (Metal Insulator Transition) material such as NbO₂, VO₂, or the like, or a tunneling insulating material having a relatively wide band gap such as SiO₂, Al₂O₃, or the like.

The variable resistance layer 45 may be a part that stores data in the memory cell 40. To this end, the variable resistance layer 45 may have a variable resistance characteristic of switching between different resistance states according to an applied voltage. The variable resistance layer 45 may have a single-layered structure or a multi-layered structure including at least one of materials used for an RRAM, a PRAM, an MRAM, an FRAM, or the like. For example, the variable resistance layer 45 may include one or more of a metal oxide (e.g., a perovskite-based oxide, a transition metal oxide, or the like), a phase change material (e.g., a chalcogenide-based material), a ferromagnetic material, a ferroelectric material, and the like. In particular, as an example, the variable resistance layer 45 may include a phase change material that switches between an amorphous state and a crystalline state by Joule's heat generated according to a current flowing therethrough. When the phase change material is in an amorphous state, the phase change material may be in a relatively high resistance state, and when the phase change material is in a crystalline state, the phase change material may be in a relatively low resistance state. Data may be stored using the difference in resistance of the phase change material.

When the intermediate electrode layer 43 includes a carbon electrode, the first interface electrode layer 44 may serve to increase adhesion while reducing a contact resistance between the intermediate electrode layer 43 and the variable resistance layer 45. Furthermore, the first interface electrode layer 44 may serve as a seed for nucleation when the variable resistance layer 45 is formed. The first interface electrode layer 44 may include a conductive material having a lower resistance than the intermediate electrode layer 43 and having good adhesive properties. For example, the first interface electrode layer 44 may include a metal such as tungsten (W), lithium (Li), aluminum (Al), tin (Sn), bismuth (Bi), antimony (Sb), nickel (Ni), copper (Cu), titanium (Ti), vanadium (V), chromium (Cr), manganese (Mn), iron (Fe), cobalt (Co), zinc (Zn), molybdenum (Mo), or the like.

When the upper electrode layer 47 includes a carbon electrode, the second interface electrode layer 46 may serve to increase adhesion while reducing a contact resistance between the upper electrode layer 47 and the variable resistance layer 45. The second interface electrode layer 46 may include a conductive material having a lower resistance than the upper electrode layer 47 and having good adhesion properties. For example, the second interface electrode layer 46 may include a metal such as tungsten (W), lithium (Li), aluminum (Al), tin (Sn), bismuth (Bi), antimony (Sb), nickel (Ni), copper (Cu), titanium (Ti), vanadium (V), chromium (Cr), manganese (Mn), iron (Fe), cobalt (Co), zinc (Zn), molybdenum (Mo), or the like.

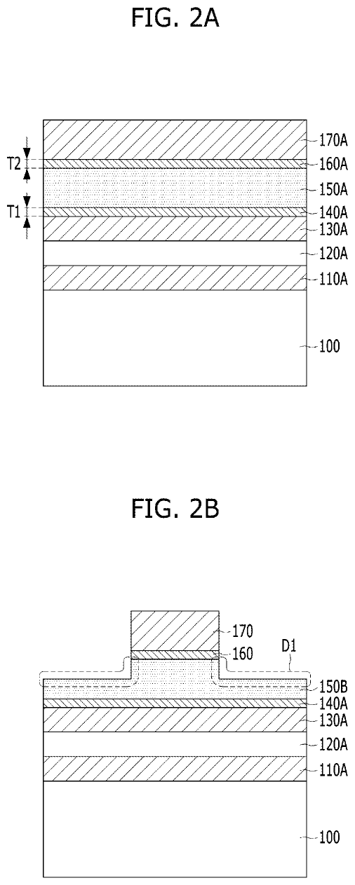

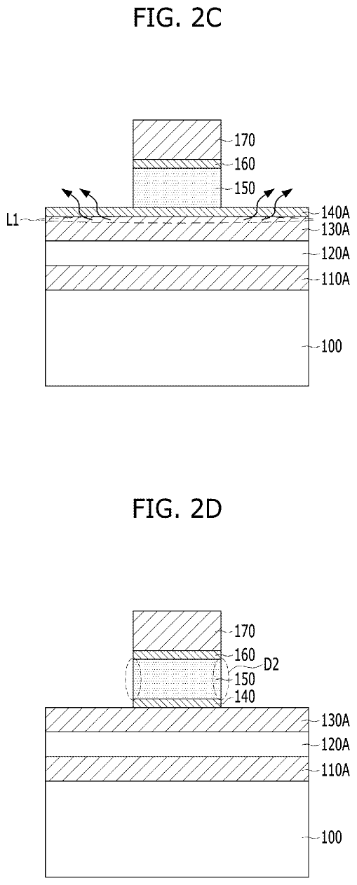

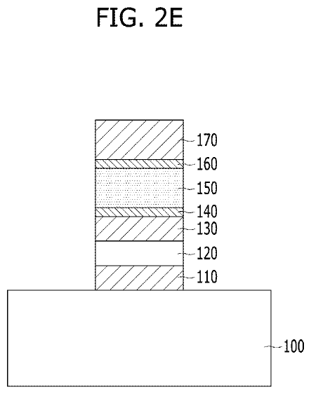

Particularly, in an embodiment, the first interface electrode layer 44, or the second interface electrode layer 46, or both may include a porous metal-containing layer having one or more pores (e.g., pinholes). This is to secure the characteristics of the memory cell 40 by substantially preventing various defects occurring during the formation process of the memory cell 40. This will be described in more detail later with reference to FIGS. 2A to 3B.

The layer structure of the memory cell 40 described above may be variously modified on the assumption that the memory cell 40 includes the variable resistance layer 45 essential for data storage.

As an example, the positions of the selection element layer 42 and the variable resistance layer 45 may be reversed. In this case, an interface electrode layer may be interposed between the variable resistance layer 45 and the lower electrode layer 41, or between the variable resistance layer 45 and the intermediate electrode layer 43, or two interface electrode layers may be respectively interposed between the variable resistance layer 45 and the lower electrode layer 41 and between the variable resistance layer 45 and the intermediate electrode layer 43.

Alternatively, as an example, although not illustrated, the memory cell 40 may further include one or more layers for improving the characteristics of the memory cell 40 in addition to the layers 41 to 47. For example, another interface electrode layer may be further interposed between the lower electrode layer 41 and the selection element layer 42, or between the selection element layer 42 and the intermediate electrode layer 43, or two additional interface electrode layers may be respectively interposed between the lower electrode layer 41 and the selection element layer 42 and between the selection element layer 42 and the intermediate electrode layer 43.

Alternatively, as an example, one or more of the lower electrode layer 41, the selection element layer 42, the intermediate electrode layer 43, the first interface electrode layer 44, the second interface electrode layer 46, and the upper electrode layer 47 may be omitted as needed. However, in order to achieve the object of embodiments of the present disclosure as will be described later, when the intermediate electrode layer 43, or the upper electrode layer 47, or both adjacent to the variable resistance layer 45 include a carbon electrode, the first interface electrode layer 44 between the intermediate electrode layer 43 and the variable resistance layer 45, the second interface electrode layer 46 between the upper electrode layer 47 and the variable resistance layer 45, or both may be present.

Hereinafter, an example of a process of forming the memory cell 40 as described above will be described with reference to FIGS. 2A to 3B.

FIGS. 2A to 2E are cross-sectional views illustrating a method of forming a memory cell according to an embodiment of the present disclosure.

Referring to FIG. 2A, a substrate 100 in which a predetermined lower structure (not shown) is formed may be provided.

Subsequently, over the substrate 100, an initial lower electrode layer 110A, an initial selection element layer 120A, an initial intermediate electrode layer 130A, an initial first interface electrode layer 140A, an initial variable resistance layer 150A, an initial second interface electrode layer 160A, and an initial upper electrode layer 170A may be sequentially formed to make an initial multi-layered structure. Formation of these layers 110A to 170A may be performed by various deposition methods.

Here, one or both of the initial first interface electrode layer 140A and the initial second interface electrode layer 160A may include a porous metal-containing layer. The initial first interface electrode layer 140A, or the initial second interface electrode layer 160A, or both and a method of forming the same will be described in more detail with reference to FIGS. 3A and 3B.

FIG. 3A is a perspective view illustrating a first interface electrode layer or a second interface electrode layer, and FIG. 3B is a cross-sectional view illustrating the first interface electrode layer or the second interface electrode layer. For example, the first interface electrode layer 140 or the second interface electrode layer 160 in FIGS. 3A and 3B may be formed by patterning the initial first interface electrode layer 140A or the initial second interface electrode layer 160A of FIG. 2A, and may be substantially the same as the first interface electrode layer 140 or the second interface electrode layer 160 of FIG. 2E.

Referring to FIGS. 3A and 3B, the first interface electrode layer 140 or the second interface electrode layer 160 may include a porous metal-containing layer having a plurality of pinholes PH. In the cross-sectional view of FIG. 3B, the plurality of pinholes PH may pass through the first interface electrode layer 140 or the second interface electrode layer 160, and a width of the pinhole PH in a horizontal direction may not be constant. For example, the width of the pinhole PH in the horizontal direction may decrease from top to bottom. However, the shape of the pinhole PH is not limited to that shown and may vary according to embodiments. In addition, although the shapes/sizes of the plurality of pinholes PH are illustrated as being substantially uniform in FIGS. 3A and 3B, embodiments of the present disclosure are not limited thereto, and the shapes/sizes of the plurality of pinholes PH may be random. That is, the plurality of pinholes PH may have different shapes/sizes.

The first interface electrode layer 140 or the second interface electrode layer 160 may be formed by a deposition method using a metal evaporation source (not shown) such as PVD (Physical Vapor Deposition). In this case, by controlling one or more process variables (e.g., an evaporation rate of the metal evaporation source), the number, or the density, or both of the pinholes PH included in the first interface electrode layer 140 or the second interface electrode layer 160 may be controlled. For example, the density of the pinholes PH may be defined as a ratio of the total area of the pinholes PH over the area of a top surface or a bottom surface of the first interface electrode layer 140 or the second interface electrode layer 160.

In addition, the first interface electrode layer 140 or the second interface electrode layer 160 may be formed to have a relatively thin thickness of several to tens of Å, and further, a thickness less than 20 Å. This may be for easily etching the first interface electrode layer 140 or the second interface electrode layer 160 even in an inert gas, as described later. For example, when the thickness of the initial first interface electrode layer 140A or the initial second interface electrode layer 160A is equal to or greater than 20 Å, etching the initial first interface electrode layer 140A and the initial second interface electrode layer 160A may be relatively difficult and require using a halogen-containing gas, leading to damage to the variable resistance layer 150 by the halogen-containing gas.

Referring back to FIG. 2A, when a thickness of the initial first interface electrode layer 140A is referred to as a first thickness T1 and a thickness of the initial second interface electrode layer 160A is referred to as a second thickness T2, the first thickness T1 and the second thickness T2 may be substantially the same. For example, the first thickness T1 may be defined as an average thickness of the initial first interface electrode layer 140A in a vertical direction with respect to the orientation of FIG. 2A, the second thickness T2 may be defined as an average thickness of the initial second interface electrode layer 160A in the vertical direction, and a difference between the first thickness T1 and the second thickness T1 may be equal to or less than 5%, 3%, 1%, 0.5%, or 0.3% of an average of the first thickness T1 and the second thickness T2.

Further, each of these thicknesses T1 and T2 may be smaller than a thickness of the initial intermediate electrode layer 130A and a thickness of the initial upper electrode layer 170A.

Referring to FIG. 2B, an upper electrode layer 170 may be formed by selectively etching the initial upper electrode layer 170A. When the upper electrode layer 170 includes a carbon electrode, the initial upper electrode layer 170A may be etched using an inert gas such as Ar.

Subsequently, a second interface electrode layer 160 may be formed by etching the initial second interface electrode layer 160A exposed by the upper electrode layer 170. Even if the second interface electrode layer 160 includes a metal, because the second interface electrode layer 160 is porous, etching may be easily performed. Furthermore, because the second interface electrode layer 160 is a film having a relatively thin thickness, etching may be more easily performed. Therefore, the initial second interface electrode layer 160A may be etched using a halogen-free gas instead of a conventional halogen-containing gas for etching a metal material. As an example, the initial second interface electrode layer 160A may be etched using an inert gas, such as Ar gas, which is used during the etching process for forming the upper electrode layer 170. Further, the initial second interface electrode layer 160A may be etched in succession to the etching process for forming the upper electrode layer 170. In other words, the initial upper electrode layer 170A and the initial second interface electrode layer 160A may be etched using the same etching gas.

Subsequently, the initial variable resistance layer 150A exposed by the second interface electrode layer 160 may be etched. FIG. 2B shows an intermediate step in which a portion of the initial variable resistance layer 150A is etched, and the partially etched initial variable resistance layer 150A will be referred to as an intermediate variable resistance layer 150B. At this time, if a halogen-containing gas was used during etching the initial second interface electrode layer 160A, a portion D1 exposed by the etching of the initial variable resistance layer 150A may be damaged by the halogen-containing gas. However, in an embodiment of the present disclosure, because the halogen-free gas was used during etching the initial second interface electrode layer 160A, damage to this portion D1 may be substantially prevented.

Referring to FIG. 2C, a variable resistance layer 150 may be formed by etching of the intermediate variable resistance layer 150B. When the variable resistance layer 150 includes a phase change material such as a chalcogenide-based material, the etching process for forming the variable resistance layer 150 may be performed using a hydrocarbon gas such as CHx gas, or the like. Furthermore, an inert gas such as Ar gas, or the like may be further used.

The hydrocarbon gas used in this etching process may pass through the initial first interface electrode layer 140A and cause a polymer gas due to carbon at a boundary L1 between the initial first interface electrode layer 140A and the initial intermediate electrode layer 130A. Specifically, the hydrocarbon gas may pass through the initial first interface electrode layer 140A and then react with carbon at the boundary L1 to generate the polymer gas. When the polymer gas is accumulated at the boundary L1, it may affect subsequent etching processes, and thus various issues may occur. As an example, planar areas of the upper and lower structures based on the boundary L1, for example, a planar area of the variable resistance layer 150 and a planar area of a selection element layer (see 120 in FIG. 2E) to be described later may be different, or a sidewall of the variable resistance layer 150 may be damaged. However, in an embodiment of the present disclosure, because the initial first interface electrode layer 140A has a plurality of pinholes, the polymer gas escapes through the pinholes (as indicated by arrows in FIG. 2C), thereby substantially preventing such issues.

Referring to FIG. 2D, a first interface electrode layer 140 may be formed by etching the initial first interface electrode layer 140A exposed by the variable resistance layer 150. Because the initial first interface electrode layer 140A includes a porous metal-containing layer, it may be etched using a halogen-free gas, for example, an inert gas. Accordingly, it may be possible to substantially prevent damage due to a halogen gas from being applied to a sidewall D2 of the variable resistance layer 150 during etching the initial first interface electrode layer 140A.

Referring to FIG. 2E, an intermediate electrode layer 130 may be formed by etching the initial intermediate electrode layer 130A exposed by the first interface electrode layer 140.

When the intermediate electrode layer 130 includes a carbon electrode, the initial intermediate electrode layer 130A may be etched using an inert gas, such as Ar gas, which is used during the etching process for forming the first interface electrode layer 140. Further, the initial intermediate electrode layer 130A may be etched in succession to the etching process for forming the first interface electrode layer 140. In other words, the initial first interface electrode layer 140A and the initial intermediate electrode layer 130A may be etched using the same etching gas.

Subsequently, a selection element layer 120 and a lower electrode layer 110 may be formed by etching the initial selection element layer 120A and the initial lower electrode layer 110A exposed by the intermediate electrode layer 130.

Accordingly, a memory cell having a multi-layered structure including the lower electrode layer 110, the selection element layer 120, the intermediate electrode layer 130, the first interface electrode layer 140, the variable resistance layer 150, the second interface electrode layer 160, and the upper electrode layer 170, may be formed.

According to the method for forming the memory cell described above, because a porous metal-containing layer is used as the first interface electrode layer 140, or the second interface electrode layer 160, or each of the first interface electrode layer 140 and the second interface electrode layer 160, an etching process for forming the memory cell may be facilitated, and it may be possible to substantially prevent the variable resistance layer 150 from being damaged during this etching process. Accordingly, it may be possible to secure the characteristics of the memory cell.

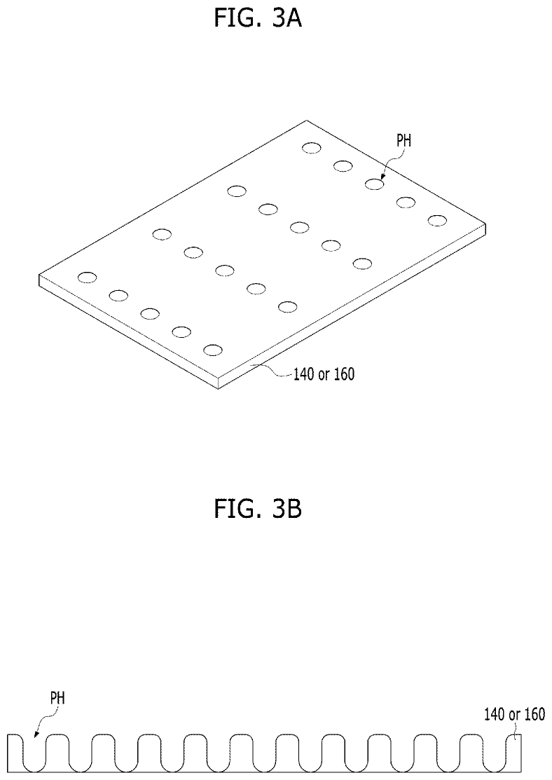

The above and other memory circuits or semiconductor devices based on the disclosed technology can be used in a range of devices or systems. FIGS. 4, 5, 6, and 7 provide some examples of devices or systems that can implement the memory circuits disclosed herein.

FIG. 4 is an example of configuration diagram of a microprocessor implementing memory circuitry based on the disclosed technology.

Referring to FIG. 4, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include various registers such as a data register, an address register, a floating point register and so on. The memory unit 1010 may perform the function of temporarily storing data for which operations are to be performed by the operation unit 1020, result data of performing the operations and addresses where data for performing of the operations are stored.

The memory unit 1010 may include one or more of the above-described semiconductor devices in accordance with the embodiments. For example, the memory unit 1010 may include a plurality of memory cells, and each memory cell includes a first electrode layer; a variable resistance layer disposed over the first electrode layer; a second electrode layer disposed over the variable resistance layer; and an interface electrode layer interposed between the first electrode layer and the variable resistance layer or between the second electrode layer and the variable resistance layer, wherein the interface electrode layer includes a porous metal-containing layer. Through this, in the memory unit 101, memory cell characteristics and fabricating processes may be improved. As a consequence, it is possible to improve operating characteristics of the microprocessor 1000.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present embodiment may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

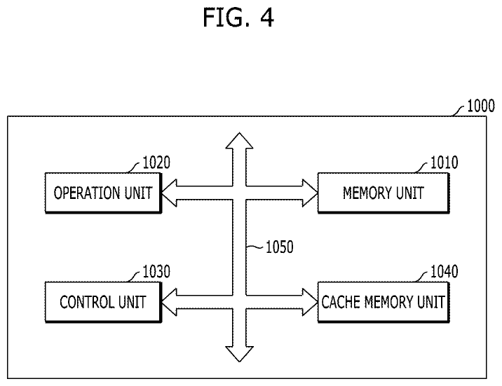

FIG. 5 is an example of configuration diagram of a processor implementing memory circuitry based on the disclosed technology.

Referring to FIG. 5, a processor 1100 may improve performance and realize multi-functionality by including various functions other than those of the above-described microprocessor 1000. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present embodiment is a part which performs arithmetic logic operations for data inputted from an external device, and may include a memory unit 1111, an operation unit 1112 and a control unit 1113. The memory unit 1111, the operation unit 1112 and the control unit 1113 may be substantially the same as the memory unit 1010, the operation unit 1020 and the control unit 1030.

The cache memory unit 1120 is a part which temporarily stores data to compensate for a difference in data processing speed between the core unit 1110 operating at a high speed and an external device operating at a low speed. The cache memory unit 1120 may include a primary storage section 1121 and a secondary storage section 1122. Further, the cache memory unit 1120 may include a tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the embodiments. For example, the cache memory unit 1120 may include a plurality of memory cells, and each memory cell includes a first electrode layer; a variable resistance layer disposed over the first electrode layer; a second electrode layer disposed over the variable resistance layer; and an interface electrode layer interposed between the first electrode layer and the variable resistance layer or between the second electrode layer and the variable resistance layer, wherein the interface electrode layer includes a porous metal-containing layer. Through this, memory cell characteristics and fabricating processes may be improved in the cache memory unit 1120. As a consequence, it is possible to improve operating characteristics of the processor 1100.

Although it was shown in this embodiment that all the primary, secondary and tertiary storage sections 1121, 1122 and 1123 are configured inside the cache memory unit 1120, at least one of the primary, secondary and tertiary storage sections 1121, 1122 and 1123 of the cache memory unit 1120 may be configured outside the core unit 1110 and may compensate for a difference in data processing speed between the core unit 1110 and the external device.

The bus interface 1130 is a part which connects the core unit 1110, the cache memory unit 1120 and external device and allows data to be efficiently transmitted.

The processor 1100 according to the present embodiment may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. Storage sections in each of the core units 1110 may be configured to be shared with storage sections outside the core units 1110 through the bus interface 1130.

The processor 1100 according to the present embodiment may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra-wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

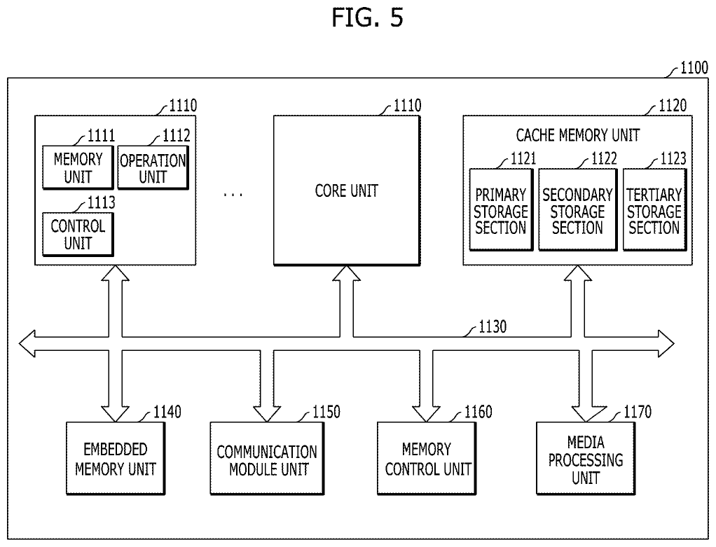

FIG. 6 is an example of configuration diagram of a system implementing memory circuitry based on the disclosed technology.

Referring to FIG. 6, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present embodiment may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may substantially the same as the above-described microprocessor 1000 or the above-described processor 1100.

The main memory device 1220 is a storage which can temporarily store, call and execute program codes or data from the auxiliary memory device 1230 when programs are executed and can conserve memorized contents even when power supply is cut off. The auxiliary memory device 1230 is a memory device for storing program codes or data. While the speed of the auxiliary memory device 1230 is slower than the main memory device 1220, the auxiliary memory device 1230 can store a larger amount of data. The main memory device 1220 or the auxiliary memory device 1230 may include one or more of the above-described semiconductor devices in accordance with the embodiments. For example, the main memory device 1220 or the auxiliary memory device 1230 may include a plurality of memory cells, and each memory cell includes a first electrode layer; a variable resistance layer disposed over the first electrode layer; a second electrode layer disposed over the variable resistance layer; and an interface electrode layer interposed between the first electrode layer and the variable resistance layer or between the second electrode layer and the variable resistance layer, wherein the interface electrode layer includes a porous metal-containing layer. Through this, memory cell characteristics and fabricating processes may be improved in the main memory device 1220 or the auxiliary memory device 1230. As a consequence, it is possible to improve operating characteristics of the system 1200.

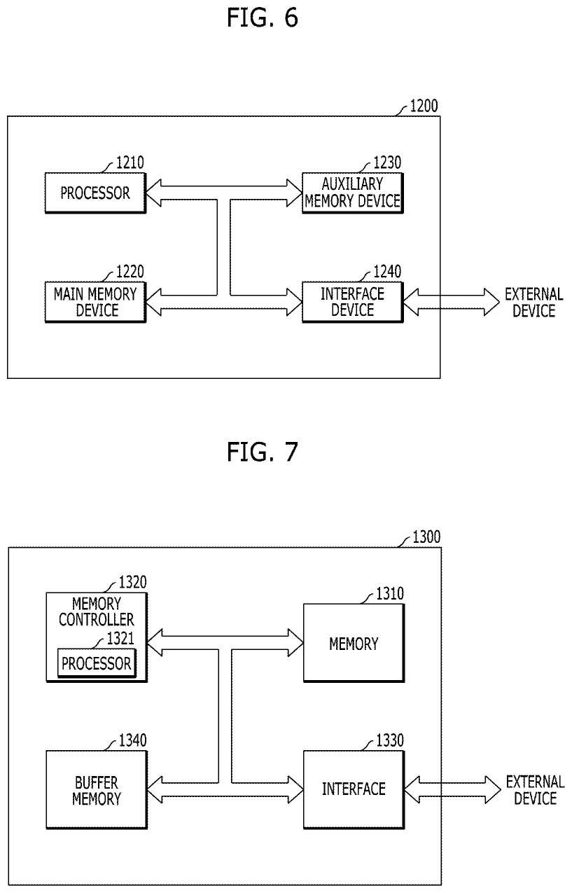

Also, the main memory device 1220 or the auxiliary memory device 1230 may include a memory system (see the reference is numeral 1300 of FIG. 7) in addition to the above-described semiconductor device or without including the above-described semiconductor device.

The interface device 1240 may be to perform exchange of commands and data between the system 1200 of the present embodiment and an external device. The interface device 1240 may be a keypad, a keyboard, a mouse, a speaker, a mike, a display, various human interface devices (HIDs), a communication device, and so on. The communication device may be substantially the same as the above-described communication module unit 1150.

FIG. 7 is an example of configuration diagram of a memory system implementing memory circuitry based on the disclosed technology.

Referring to FIG. 7, a memory system 1300 may include a memory 1310 which has a nonvolatile characteristic as a component for storing data, a controller 1320 which controls the memory 1310, an interface 1330 for connection with an external device, and a buffer memory 1340 for storing data temporarily for efficiently transferring data between the interface 1330 and the memory 1310. The memory system 1300 may simply mean a memory for storing data, and may also mean a data storage device for conserving stored data in a long term. The memory system 1300 may be a disk type such as a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1310 or the buffer memory 1340 may include one or more of the above-described semiconductor devices in accordance with the embodiments. For example, the memory 1310 or the buffer memory 1340 may include a plurality of memory cells, and each memory cell includes a first electrode layer; a variable resistance layer disposed over the first electrode layer; a second electrode layer disposed over the variable resistance layer; and an interface electrode layer interposed between the first electrode layer and the variable resistance layer or between the second electrode layer and the variable resistance layer, wherein the interface electrode layer includes a porous metal-containing layer. Through this, in the memory 1310 or the buffer memory 1340, memory cell characteristics and fabricating processes may be improved. As a consequence, it is possible to improve operating characteristics of the memory system 1300.

The memory 1310 or the buffer memory 1340 may include various memories such as a nonvolatile memory or a volatile memory, in addition to the above-described semiconductor device or without including the above-described semiconductor device.

The controller 1320 may control exchange of data between the memory 1310 and the interface 1330. To this end, the controller 1320 may include a processor 1321 for performing an operation for, processing commands inputted through the interface 1330 from an outside of the memory system 1300 and so on.

The interface 1330 is to perform exchange of commands and data between the memory system 1300 and the external device. In the case where the memory system 1300 is a card type or a disk type, the interface 1330 may be compatible with interfaces which are used in devices having a card type or a disk type, or be compatible with interfaces which are used in devices similar to the above mentioned devices. The interface 1330 may be compatible with one or more interfaces having a different type from each other.

Features in the above examples of electronic devices or systems in FIGS. 4-7 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of the present disclosure. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

A few embodiments and examples are described herein. Other embodiments, enhancements and variations can be made based on what is described and illustrated in this patent document.

Although various embodiments have been described for illustrative purposes, it will be apparent to those skilled in the art that various changes and modifications may be made without departing from the spirit and scope of teachings of the present disclosure as defined in the following claims.

What is claimed is:

1. An electronic device comprising a semiconductor memory, the semiconductor memory including a plurality of memory cells, each of the plurality of memory cells comprising:
a first electrode layer;
a variable resistance layer disposed over the first electrode layer;
a second electrode layer disposed over the variable resistance layer; and
an interface electrode layer interposed between the first electrode layer and the variable resistance layer or between the second electrode layer and the variable resistance layer,
wherein the interface electrode layer includes a porous metal-containing layer.

2. The electronic device according to claim 1, wherein a thickness of the interface electrode layer is less than 20 Å.

3. The electronic device according to claim 1, wherein a thickness of the interface electrode layer is smaller than a thickness of the first electrode layer and a thickness of the second electrode layer.

4. The electronic device according to claim 1, wherein the interface electrode layer has a plurality of pinholes penetrating therethrough.

5. The electronic device according to claim 1, wherein the first electrode layer, or the second electrode layer, or both include a carbon electrode.

6. The electronic device according to claim 5, wherein the interface electrode layer includes a material having a lower resistance than the carbon electrode.

7. The electronic device according to claim 1, wherein the variable resistance layer includes a phase change material.

8. The electronic device according to claim 1, wherein each of the plurality of memory cells further comprises:
a third electrode layer; and
a selection element layer interposed between the first electrode layer and the third electrode layer or between the second electrode layer and the third electrode layer.

9. The electronic device according to claim 1, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the semiconductor memory is part of the memory unit in the microprocessor.

10. The electronic device according to claim 1, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory is part of the cache memory unit in the processor.

11. The electronic device according to claim 1, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the semiconductor memory is part of the auxiliary memory device or the main memory device in the processing system.

12. The electronic device according to claim 1, further comprising a memory system which includes:
a memory configured to store data and conserve stored data regardless of power supply;
a memory controller configured to control input and output of data to and from the memory according to a command inputted from an outside;
a buffer memory configured to buffer data exchanged between the memory and the outside; and
an interface configured to perform communication between at least one of the memory, the memory controller and the buffer memory and the outside,
wherein the semiconductor memory is part of the memory or the buffer memory in the memory system.

13. The electronic device according to claim 1, wherein the interface electrode layer is a first interface electrode layer and interposed between the first electrode layer and the variable resistance layer, the device further comprising a second interface electrode layer interposed between the second electrode layer and the variable resistance layer.

14. A method for fabricating an electronic device, wherein the electronic device comprises a semiconductor memory including a plurality of memory cells, the method comprising:
forming an initial multi-layered structure for forming the plurality of memory cells over a substrate, the initial multi-layered structure including an initial first electrode layer, an initial variable resistance layer disposed over the initial first electrode layer, an initial second electrode layer disposed over the initial variable resistance layer, and an initial interface electrode layer interposed between the initial first electrode layer and the initial variable resistance layer or between the initial second electrode layer and the initial variable resistance layer; and
selectively etching the initial multi-layered structure to form a multi-layered structure including a first electrode layer, a variable resistance layer disposed over the first electrode layer, a second electrode layer disposed over the variable resistance layer, and an interface electrode layer interposed between the first electrode layer and the variable resistance layer or between the second electrode layer and the variable resistance layer,
wherein the interface electrode layer includes a porous metal-containing layer.

15. The method according to claim 14, wherein a thickness of the interface electrode layer is less than 20 Å.

16. The method according to claim 14, wherein etching the initial multi-layered structure includes etching the initial interface electrode layer using a halogen-free gas.

17. The method according to claim 16, wherein the halogen-free gas includes an inert gas.

18. The method according to claim 14, wherein the second electrode layer includes a carbon electrode, and the interface electrode layer is interposed between the second electrode layer and the variable resistance layer, and
wherein etching the initial multi-layered structure includes etching the initial second electrode layer and the initial interface electrode layer using an inert gas to form the second electrode layer and the interface electrode layer.

19. The method according to claim 14, wherein the first electrode layer includes a carbon electrode, and the interface electrode layer is interposed between the first electrode layer and the variable resistance layer, and
wherein etching the initial multi-layered structure includes etching the initial first electrode layer and the initial interface electrode layer using an inert gas to form the first electrode layer and the interface electrode layer.

20. The method according to claim 14, wherein the variable resistance layer includes a phase change material, and
etching the initial multi-layered structure includes etching the initial variable resistance layer using a hydrocarbon gas to form the variable resistance layer.

21. The method according to claim 20, wherein a polymer gas generated during etching the initial variable resistance layer passes through the initial interface electrode layer.

22. The method according to claim 14, wherein a thickness of the interface electrode layer is smaller than a thickness of the first electrode layer and a thickness of the second electrode layer.

23. The method according to claim 14, wherein the interface electrode layer has a plurality of pinholes penetrating therethrough.

24. The method according to claim 14, wherein the first electrode layer, or the second electrode layer, or both include a carbon electrode.

25. The method according to claim 24, wherein the interface electrode layer includes a material having a lower resistance than the carbon electrode.

26. The method according to claim 14, wherein the multi-layered structure further includes:
a third electrode layer; and
a selection element layer interposed between the first electrode layer and the third electrode layer or between the second electrode layer and the third electrode layer.
